(19) United States
(12) Patent Application Publication
(10) Pub. No.: US 2026/0060082 A1
(43) Pub. Date: Feb. 26, 2026

(54) HIGHLY CONDUCTIVE AND HEAT-DISSIPATING CHIP AND MANUFACTURING METHOD THEREOF

(71) Applicant: HLJ TECHNOLOGY CO., LTD., Hsinchu County (TW)

(72) Inventors: LI-HUNG LAI, Taoyuan City (TW); LI-WEN LAI, Taoyuan City (TW); YEN-CHU LI, Miaoli County (TW)

(21) Appl. No.: 18/961,389

(22) Filed: Nov. 26, 2024

(30) Foreign Application Priority Data
Aug. 23, 2024 (TW) 113131694

(51) Int. Cl. H01L 23/373; H01L 21/027; H01L 21/308; H01L 21/3205; H01L 23/367

(52) U.S. Cl. CPC H01L 23/3736; H01L 21/0274; H01L 21/3086; H01L 21/32051; H01L 23/367

(57) ABSTRACT

A highly conductive and heat-dissipating chip and a manufacturing method thereof are provided. The manufacturing method includes: providing a substrate having a first surface and a second surface that is opposite to the first surface; forming a groove having at least one arc shape on the substrate; and filling a heat-dissipating material into the groove. Accordingly, a heat dissipation effect of the substrate can be enhanced, a structure of the substrate can be protected, and a service life of the substrate can be prolonged.

### CROSS-REFERENCE TO RELATED PATENT APPLICATION

This application claims the benefit of priority to Taiwan Patent Application No. 113131694, filed on Aug. 23, 2024. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a chip and a manufacturing method thereof, and more particularly to a manufacturing method and a structure of a highly conductive and heat-dissipating chip.

### BACKGROUND OF THE DISCLOSURE

Semiconductors have a wide application and are largely used in consumer products or electronic devices, such as a laser device, a rectifier, an oscillator, a light emitter, an amplifier, and a photometer.

With the advancement of technology, semiconductors that are used as electronic components are being designed with the purpose of simplification in mind. However, common wafer materials (e.g., silicon, germanium, or gallium arsenide) have low coefficients of thermal and electrical conductivity, thereby resulting in poor thermal and electrical conduction effects. When the wafer materials are used in the electronic components having high power, damage is likely to occur due to thermal expansion or thermal stress.

In the conventional technology, metal materials that are thermally and electrically conductive can be added into semiconductor materials. However, since the metal materials and the semiconductor materials have different expansion coefficients, internal stress is easily generated and can damage the semiconductor materials (e.g., a wafer).

Therefore, how to enhance thermal and electrical conduction effects of a wafer or a chip through improvements in the structural design, so as to overcome the above-mentioned problems, has become one of the important issues to be solved in the relevant industry.

### SUMMARY OF THE DISCLOSURE

In response to the above-referenced technical inadequacies, the present disclosure provides a highly conductive and heat-dissipating chip and a manufacturing method thereof.

In order to solve the above-mentioned problems, one of the technical aspects adopted by the present disclosure is to provide a manufacturing method of a highly conductive and heat-dissipating chip. The manufacturing method includes: providing a substrate, in which the substrate has a first surface and a second surface that is opposite to the first surface, and the substrate is disposed on a carrier; polishing the second surface of the substrate; coating a first photoresist onto the second surface for formation of a first photoresist layer; exposing the first photoresist layer through a first mask, such that a predetermined pattern is formed on the first photoresist layer, and the predetermined pattern includes at least one arc shape; developing the first photoresist layer, so as to form a plurality of trenches that correspond to the predetermined pattern; etching the substrate in accordance with the trenches, so as to form at least one groove in the substrate; removing the first photoresist layer; sputtering a seed crystal layer onto the substrate, in which the seed crystal layer covers the second surface and a base wall of the at least one groove; coating a second photoresist for formation of a second photoresist layer on the seed crystal layer; exposing the second photoresist layer through a second mask, so as to form an electroplating area on the second photoresist layer that is positioned within the at least one groove; developing the second photoresist layer for removal of the electroplating area; electroplating a metal material within the at least one groove, in which the at least one groove is filled with the metal material; removing the second photoresist layer; and peeling the substrate from the carrier.

In one of the possible or preferred embodiments, the predetermined pattern is a pattern of a vortex, and one end of the vortex is positioned at an edge of the substrate.

In one of the possible or preferred embodiments, the substrate has a thickness of less than or equal to 100 μm after being polished.

In one of the possible or preferred embodiments, the at least one groove has a depth of greater than or equal to 90 μm.

In order to solve the above-mentioned problems, another one of the technical aspects adopted by the present disclosure is to provide a manufacturing method of a highly conductive and heat-dissipating chip. The manufacturing method includes: providing a substrate, in which the substrate has a first surface and a second surface that is opposite to the first surface, and the substrate is disposed on a carrier; polishing the second surface of the substrate; sputtering a seed crystal layer onto the second surface of the substrate; electroplating a metal material onto the seed crystal layer for formation of a metal layer that corresponds in position to the second surface; and peeling the substrate from the carrier.

In one of the possible or preferred embodiments, the substrate has a thickness of less than or equal to 10 μm after being polished.

In one of the possible or preferred embodiments, the metal layer has a thickness of greater than or equal to 90 μm.

In one of the possible or preferred embodiments, the manufacturing method further includes a dividing process for cutting the substrate into a plurality of chips after the substrate is peeled from the carrier.

In one of the possible or preferred embodiments, the substrate is a gallium arsenide substrate, and the carrier is a sapphire substrate.

In one of the possible or preferred embodiments, the above-mentioned seed crystal layer is at least one of titanium (Ti), nickel (Ni), copper (Cu), chromium (Cr), silver (Ag), gold (Au), palladium (Pd), carbon (C), tin (Sn), tungsten (W), titanium/copper (Ti/Cu), titanium/silver (Ti/Ag), titanium/nickel (Ti/Ni), chromium/copper (Cr/Cu), chromium/silver (Cr/Ag), or chromium/nickel (Cr/Ni), or an alloy or a combination thereof.

In one of the possible or preferred embodiments, the above-mentioned metal material is at least one of titanium (Ti), nickel (Ni), copper (Cu), chromium (Cr), silver (Ag), gold (Au), tin (Sn), palladium (Pd), nickel/gold (Ni/Au), nickel/palladium/gold (Ni/Pd/Au), nickel/silver (Ni/Ag), or copper/nickel/silver (Cu/Ni/Ag), or an alloy or a combination thereof.

In order to solve the above-mentioned problems, yet another one of the technical aspects adopted by the present disclosure is to provide a highly conductive and heat-dissipating chip, which includes a chip body, a seed crystal layer, and a filler body. The chip body has a first surface and a second surface, the chip body has at least one groove that is formed on the second surface, and at least one portion of the at least one groove has an arc shape. The seed crystal layer is disposed on the second surface and a base wall of the at least one groove. The filler body is a metal material, and is filled into the at least one groove.

In one of the possible or preferred embodiments, the chip body has a thickness of less than or equal to 100 μm.

In one of the possible or preferred embodiments, the at least one groove has a depth of greater than or equal to 90 μm.

In one of the possible or preferred embodiments, the at least one groove of the chip body has a shape of a vortex.

In one of the possible or preferred embodiments, one end of the above-mentioned vortex is positioned at an edge of the chip body.

In order to solve the above-mentioned problems, still yet another one of the technical aspects adopted by the present disclosure is to provide a highly conductive and heat-dissipating chip, which includes a chip body, a seed crystal layer, and a metal layer. The chip body has a first surface and a second surface. The seed crystal layer is disposed on the second surface. The metal layer is formed by a metal material, and is disposed on the seed crystal layer. The chip body has a thickness of less than or equal to 10 μm. The metal layer has a thickness of greater than or equal to 90 μm.

In one of the possible or preferred embodiments, the seed crystal layer of the highly conductive and heat-dissipating chip is at least one of titanium (Ti), nickel (Ni), copper (Cu), chromium (Cr), silver (Ag), gold (Au), palladium (Pd), carbon (C), tin (Sn), tungsten (W), titanium/copper (Ti/Cu), titanium/silver (Ti/Ag), titanium/nickel (Ti/Ni), chromium/copper (Cr/Cu), chromium/silver (Cr/Ag), or chromium/nickel (Cr/Ni), or an alloy or a combination thereof.

In one of the possible or preferred embodiments, the metal material of the highly conductive and heat-dissipating chip is at least one of titanium (Ti), nickel (Ni), copper (Cu), chromium (Cr), silver (Ag), gold (Au), tin (Sn), palladium (Pd), nickel/gold (Ni/Au), nickel/palladium/gold (Ni/Pd/Au), nickel/silver (Ni/Ag), or copper/nickel/silver (Cu/Ni/Ag), or an alloy or a combination thereof.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 (FIG. 1A and FIG. 1B) is a flowchart of a manufacturing method of a highly conductive and heat-dissipating chip according to one embodiment of the present disclosure;

FIG. 2 is a schematic view of an outer appearance of the highly conductive and heat-dissipating chip according to one embodiment of the present disclosure;

FIG. 3 is a partial cross-sectional view of the embodiment shown in FIG. 2;

FIG. 4 is a flowchart of a manufacturing method of a highly conductive and heat-dissipating chip according to another embodiment of the present disclosure;

FIG. 5 is a schematic view of an outer appearance of the highly conductive and heat-dissipating chip according to another embodiment of the present disclosure; and

FIG. 6 is a cross-sectional view of the embodiment shown in FIG. 5.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on. ” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

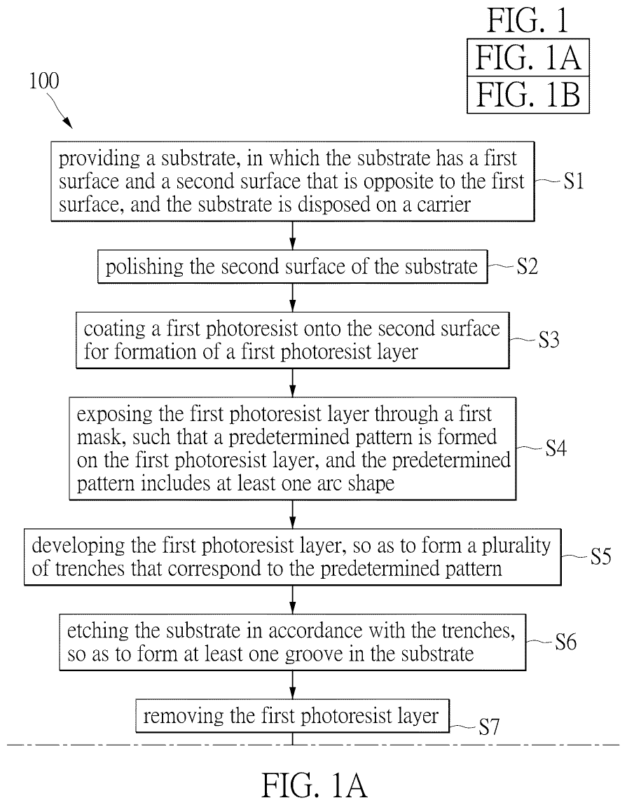

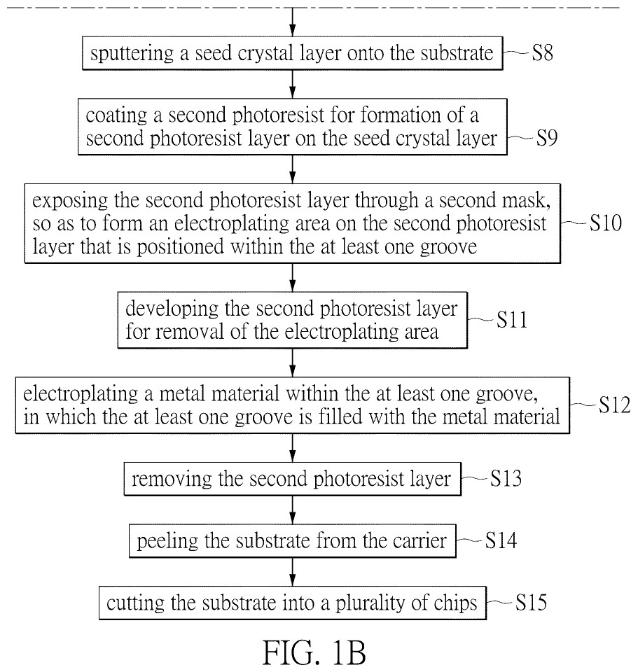

Reference is made to FIG. 1 (FIG. 1A and FIG. 1B), which is a flowchart of a manufacturing method of a highly conductive and heat-dissipating chip according to one embodiment of the present disclosure. A manufacturing method 100 of the highly conductive and heat-dissipating chip at least includes step S1 to step S14.
Step S1: providing a substrate, in which the substrate has a first surface and a second surface that is opposite to the first surface, and the substrate is disposed on a carrier. In certain embodiments, the substrate is a gallium arsenide substrate (a wafer). The carrier is, for example but not limited to, sapphire.
Step S2: polishing the second surface of the substrate. In certain embodiments, the substrate has a thickness of less than or equal to 100 μm after being polished, so as to form a thin film layer.
Step S3: coating a first photoresist onto the second surface for formation of a first photoresist layer.
Step S4: exposing the first photoresist layer through a first mask, such that a predetermined pattern is formed on the first photoresist layer, and the predetermined pattern includes at least one arc shape. According to certain embodiments, a photoresist layer is exposed by yellow light. The predetermined pattern can be, for example, a circular shape, a bracket shape, or a U shape. According to certain embodiments, the predetermined pattern is a pattern of a vortex.
Step S5: developing the first photoresist layer, so as to form a plurality of trenches that correspond to the predetermined pattern.
Step S6: etching the substrate in accordance with the trenches, so as to form at least one groove in the substrate. In certain embodiments, along a horizontal direction, one end of the at least one groove is positioned at an edge of the substrate. According to certain embodiments, the at least one groove has a depth of greater than or equal to 90 μm after being etched.

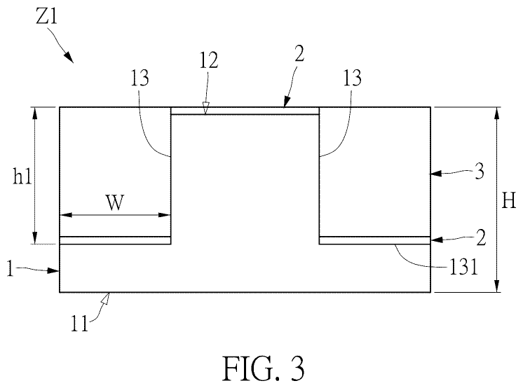

In certain embodiments, a width W of the at least one groove ranges between 5 μm and 10 μm, or is 8 μm (as shown in FIG. 3).
Step S7: removing the first photoresist layer.
Step S8: sputtering a seed crystal layer onto the substrate. The seed crystal layer covers the second surface and a base wall of the at least one groove (as shown in FIG. 3). According to certain embodiments, the seed crystal layer is at least one of titanium (Ti), nickel (Ni), copper (Cu), chromium (Cr), silver (Ag), gold (Au), palladium (Pd), carbon (C), tin (Sn), tungsten (W), titanium/copper (Ti/Cu), titanium/silver (Ti/Ag), titanium/nickel (Ti/Ni), chromium/copper (Cr/Cu), chromium/silver (Cr/Ag), or chromium/nickel (Cr/Ni), or an alloy or a combination thereof. According to certain embodiments, the seed crystal layer is titanium-tungsten alloy and gold (TiW/Au).
Step S9: coating a second photoresist for formation of a second photoresist layer on the seed crystal layer.
Step S10: exposing the second photoresist layer through a second mask, so as to form an electroplating area on the second photoresist layer that is positioned within the at least one groove.
Step S11: developing the second photoresist layer for removal of the electroplating area.
Step S12: electroplating a metal material within the at least one groove, in which the at least one groove is filled with the metal material. According to certain embodiments, the metal material is at least one of titanium (Ti), nickel (Ni), copper (Cu), chromium (Cr), silver (Ag), gold (Au), tin (Sn), palladium (Pd), nickel/gold (Ni/Au), nickel/palladium/gold (Ni/Pd/Au), nickel/silver (Ni/Ag), or copper/nickel/silver (Cu/Ni/Ag), or an alloy or a combination thereof. According to certain embodiments, a copper metal is filled into the at least one groove for having a good thermal conduction effect.
Step S13: removing the second photoresist layer.
Step S14: peeling the substrate from the carrier. According to certain embodiments, an adhesive layer between the substrate and the carrier can be softened via light-based heating or other ways of heating, such that the substrate and the carrier are in a separable state.

In the embodiment shown in FIG. 1 (FIG. 1A and FIG. 1B), the manufacturing method 100 further includes step S15 (a dividing process). After step S14, step S15 is performed to cut the substrate into a plurality of chips. It should be noted that, after cutting, each of the chips includes a chip body, the seed crystal layer, and the metal material that is filled into the at least one groove (details thereof are provided below).

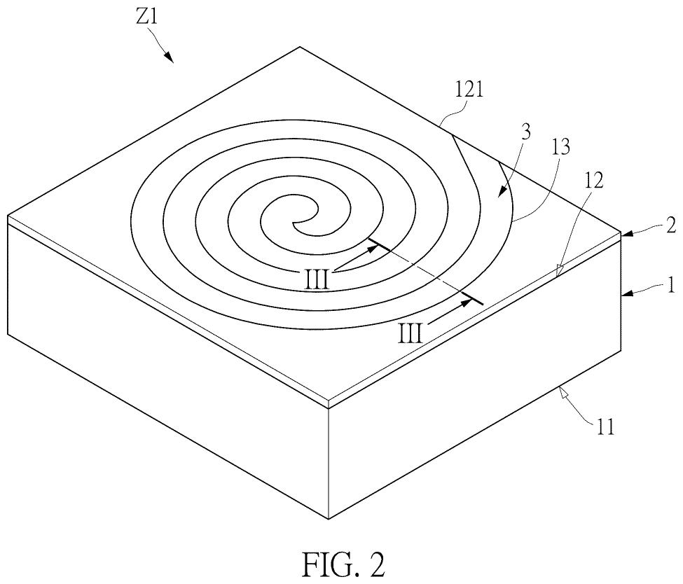

Referring to FIG. 2 and FIG. 3, FIG. 2 is a schematic view of an outer appearance of a highly conductive and heat-dissipating chip Z1 according to one embodiment of the present disclosure, and FIG. 3 is a partial cross-sectional view of the embodiment shown in FIG. 2. In this embodiment, the highly conductive and heat-dissipating chip Z1 includes a chip body 1, a seed crystal layer 2, and a filler body 3. The chip body 1 has a first surface 11 and a second surface 12. The chip body 1 has a groove 13 that is formed on the second surface 12, and at least one portion of the groove 13 has an arc shape. As shown in FIG. 2, the groove 13 has a shape of a vortex. One end of the vortex is positioned at an edge of the chip body 1. The seed crystal layer 2 is disposed on the second surface 12 and a base wall 131 of the groove 13 (as shown in FIG. 3). The filler body 3 is the metal material, and is filled into the groove 13.

According to certain embodiments, the seed crystal layer 2 is at least one of titanium (Ti), nickel (Ni), copper (Cu), chromium (Cr), silver (Ag), gold (Au), palladium (Pd), carbon (C), tin (Sn), tungsten (W), titanium/copper (Ti/Cu), titanium/silver (Ti/Ag), titanium/nickel (Ti/Ni), chromium/copper (Cr/Cu), chromium/silver (Cr/Ag), or chromium/nickel (Cr/Ni), or an alloy or a combination thereof.

According to certain embodiments, the metal material is at least one of titanium (Ti), nickel (Ni), copper (Cu), chromium (Cr), silver (Ag), gold (Au), tin (Sn), palladium (Pd), nickel/gold (Ni/Au), nickel/palladium/gold (Ni/Pd/Au), nickel/silver (Ni/Ag), or copper/nickel/silver (Cu/Ni/Ag), or an alloy or a combination thereof. According to certain embodiments, the groove 13 is filled with the copper metal.

According to certain embodiments, the chip body 1 has a thickness H of less than or equal to 100 μm.

According to certain embodiments, the groove 13 has a depth h1 of greater than or equal to 90 μm.

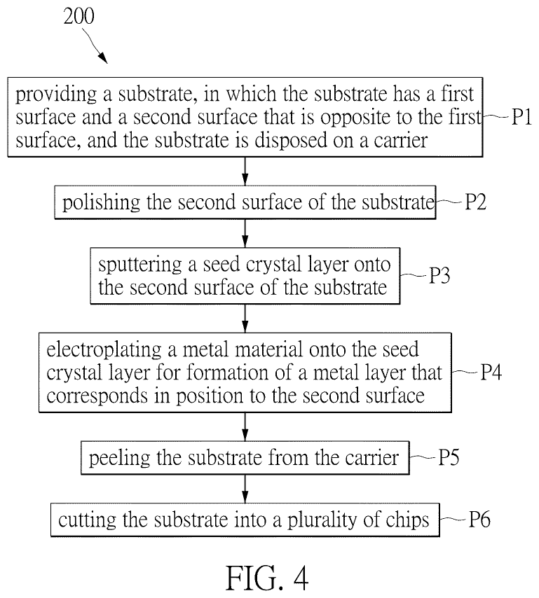

Reference is made to FIG. 4, which is a flowchart of a manufacturing method of a highly conductive and heat-dissipating chip according to another embodiment of the present disclosure. In this embodiment, a manufacturing method 200 of the highly conductive and heat-dissipating chip at least includes step P1 to step P5.
Step P1: providing a substrate, in which the substrate has a first surface and a second surface that is opposite to the first surface, and the substrate is disposed on a carrier.
Step P2: polishing the second surface of the substrate. According to certain embodiments, the substrate has a thickness of less than or equal to 10 μm after being polished.
Step P3: sputtering a seed crystal layer onto the second surface of the substrate.
Step P4: electroplating a metal material onto the seed crystal layer for formation of a metal layer that corresponds in position to the second surface. The metal layer has a thickness of greater than or equal to 90 μm.
Step P5: peeling the substrate from the carrier.

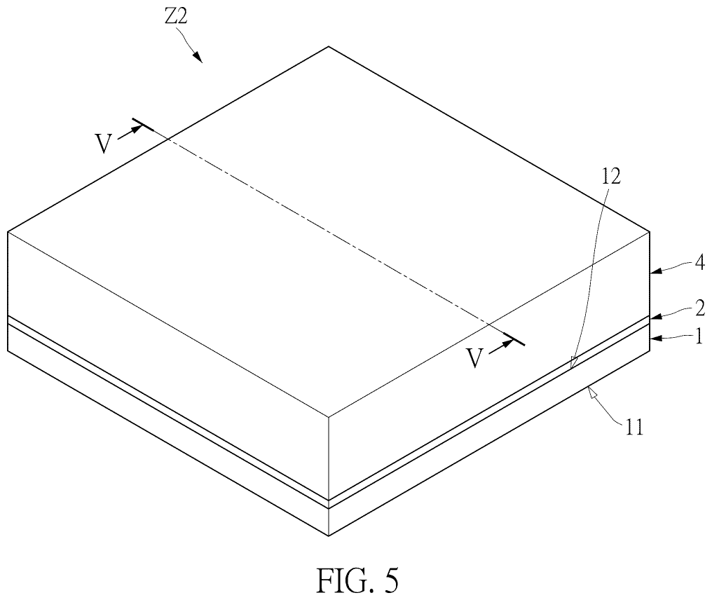

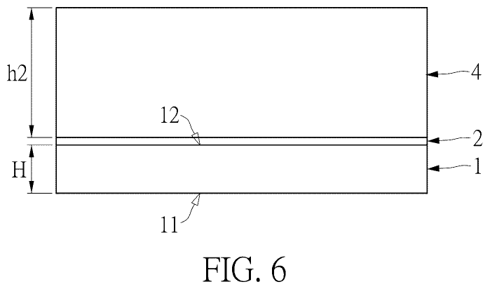

Regarding the metal layer and the seed crystal layer, reference can be made to the descriptions above. The difference between the embodiments shown in FIG. 4 and FIG. 1 (FIG. 1A and FIG. 1B) is that, while the metal material of FIG. 1 (FIG. 1A and FIG. 1B) is filled into the at least one groove, the metal material of FIG. 4 is formed into the metal layer that covers the seed crystal layer (as shown in FIG. 5 or FIG. 6).

In this embodiment, the manufacturing method 200 further includes step P6 (a dividing process). After step P5, step P6 is performed to cut the substrate into a plurality of chips. According to certain embodiments, after cutting, each of the chips includes a chip body, the seed crystal layer, and the metal layer (details thereof are provided below).

Referring to FIG. 5 and FIG. 6, FIG. 5 is a schematic view of an outer appearance of a highly conductive and heat-dissipating chip Z2 according to another embodiment of the present disclosure, and FIG. 6 is a cross-sectional view of the embodiment shown in FIG. 5. The highly conductive and heat-dissipating chip Z2 includes a chip body 1, a seed crystal layer 2, and a metal layer 4. The chip body 1 has a first surface 11 and a second surface 12, and the seed crystal layer 2 is disposed on the second surface 12. The metal layer 4 is formed by the metal material, and is disposed on the seed crystal layer 2. The chip body 1 has a thickness H of less than or equal to 10 μm, and the metal layer 4 has a thickness h2 of greater than or equal to 90 μm.

Regarding the structure and the material of the chip body 1, the seed crystal layer 2, and the metal layer 4, reference can be made to the descriptions above. The difference between the embodiments shown in FIG. 5 and FIG. 2 is that, while the metal material of the highly conductive and heat-dissipating chip Z1 in FIG. 2 is filled into the groove 13, the metal material of the highly conductive and heat-dissipating chip Z2 in FIG. 6 is formed into the metal layer 4 that covers the seed crystal layer 2.

### Beneficial Effects of the Embodiments

In conclusion, in the manufacturing method of the highly conductive and heat-dissipating chip provided by the present disclosure, by virtue of “electroplating the metal material within the at least one groove of the substrate, in which the at least one groove is filled with the metal material,” a thin-layer substrate (chip) is designed to have a heat dissipation structure, and is filled with a heat-dissipating material. In this way, the problem of high heat generated during use of the substrate (chip) can be improved, thereby enhancing a heat dissipation effect of the substrate (chip), protecting a structure of the substrate (chip), and prolonging a service life of the substrate (chip).

In the highly conductive and heat-dissipating chip provided by the present disclosure, by virtue of “the substrate (chip) having the at least one groove that is formed on the second surface, and the at least one portion of the at least one groove having the arc shape” and “the filler body being the metal material and being filled into the at least one groove,” a heat dissipation function of the thin-layer substrate (chip) can be enhanced, so as to improve a heat dissipation problem when in use. Accordingly, the structure of the substrate (chip) can be strengthened, and the service life of the substrate (chip) can be prolonged.

Moreover, since a groove has at least one arc shape, a metal material filled into the groove can effectively resist thermal stress within the substrate (chip). As such, damage to the chip due to thermal expansion does not occur. In one embodiment, the groove has a shape of a vortex, and one end of the groove is positioned at an edge of the chip.

In the manufacturing method of the highly conductive and heat-dissipating chip provided by the present disclosure, by virtue of “electroplating the metal material onto the second surface for formation of the metal layer,” a metal layer can fully cover a surface of the substrate (chip), thereby further enhancing a heat dissipation effect of a high-power chip, protecting the structure of the substrate (chip), and prolonging the service life of the substrate (chip).

Furthermore, in the highly conductive and heat-dissipating chip provided by the present disclosure, by virtue of “the metal layer being formed by the metal material and being disposed on the seed crystal layer” and “the chip body having the thickness of less than or equal to 10 μm, and the metal layer having the thickness of greater than or equal to 90 μm,” the metal layer is disposed on the surface of the thin-layer substrate (chip). Hence, the heat dissipation effect of the high-power chip can be enhanced, the structure of the substrate (chip) can be protected, and the service life of the substrate (chip) can be prolonged.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A manufacturing method of a highly conductive and heat-dissipating chip, comprising:
providing a substrate, wherein the substrate has a first surface and a second surface that is opposite to the first surface, the substrate is disposed on a carrier, and the second surface is outwardly exposed;
polishing the second surface of the substrate;
coating a first photoresist onto the second surface for formation of a first photoresist layer;
exposing the first photoresist layer through a first mask, such that a predetermined pattern is formed on the first photoresist layer, and the predetermined pattern includes at least one arc shape;
developing the first photoresist layer, so as to form a plurality of trenches that correspond to the predetermined pattern;
etching the substrate in accordance with the plurality of trenches, so as to form at least one groove in the substrate;
removing the first photoresist layer;
sputtering a seed crystal layer onto the substrate, wherein the seed crystal layer covers the second surface and a base wall of the at least one groove;
coating a second photoresist for formation of a second photoresist layer on the seed crystal layer;
exposing the second photoresist layer through a second mask, so as to form an electroplating area on the second photoresist layer that is positioned within the at least one groove;
developing the second photoresist layer for removal of the electroplating area;
electroplating a metal material within the at least one groove, wherein the at least one groove is filled with the metal material;
removing the second photoresist layer; and
peeling the substrate from the carrier.

2. The manufacturing method according to claim 1, further comprising: a dividing process for cutting the substrate into a plurality of chips after the substrate is peeled from the carrier.

3. The manufacturing method according to claim 1, wherein the substrate is a gallium arsenide substrate, and the carrier is a sapphire substrate.

4. The manufacturing method according to claim 1, wherein the seed crystal layer is at least one of titanium (Ti), nickel (Ni), copper (Cu), chromium (Cr), silver (Ag), gold (Au), palladium (Pd), carbon (C), tin (Sn), tungsten (W), titanium/copper (Ti/Cu), titanium/silver (Ti/Ag), titanium/nickel (Ti/Ni), chromium/copper (Cr/Cu), chromium/silver (Cr/Ag), or chromium/nickel (Cr/Ni), or an alloy or a combination thereof.

5. The manufacturing method according to claim 1, wherein the metal material is at least one of titanium (Ti), nickel (Ni), copper (Cu), chromium (Cr), silver (Ag), gold (Au), tin (Sn), palladium (Pd), nickel/gold (Ni/Au), nickel/palladium/gold (Ni/Pd/Au), nickel/silver (Ni/Ag), or copper/nickel/silver (Cu/Ni/Ag), or an alloy or a combination thereof.

6. The manufacturing method according to claim 1, wherein the predetermined pattern is a pattern of a vortex.

7. The manufacturing method according to claim 1, wherein one end of the at least one groove is positioned at an edge of the substrate.

8. The manufacturing method according to claim 1, wherein the substrate has a thickness of less than or equal to 100 μm after being polished.

9. The manufacturing method according to claim 1, wherein the at least one groove has a depth of greater than or equal to 90 μm.

10. The manufacturing method according to claim 1, wherein the substrate has a thickness of less than or equal to 10 μm after being polished.

11. A manufacturing method of a highly conductive and heat-dissipating chip, comprising:
providing a substrate, wherein the substrate has a first surface and a second surface that is opposite to the first surface, the substrate is disposed on a carrier, and the second surface is outwardly exposed;
polishing the second surface of the substrate;
sputtering a seed crystal layer onto the second surface of the substrate;
electroplating a metal material onto the seed crystal layer for formation of a metal layer that corresponds in position to the second surface; and
peeling the substrate from the carrier.

12. The manufacturing method according to claim 11, further comprising: a dividing process for cutting the substrate into a plurality of chips after the substrate is peeled from the carrier.

13. The manufacturing method according to claim 11, wherein the substrate is a gallium arsenide substrate, and the carrier is a sapphire substrate.

14. The manufacturing method according to claim 11, wherein the seed crystal layer is at least one of titanium (Ti), nickel (Ni), copper (Cu), chromium (Cr), silver (Ag), gold (Au), palladium (Pd), carbon (C), tin (Sn), tungsten (W), titanium/copper (Ti/Cu), titanium/silver (Ti/Ag), titanium/nickel (Ti/Ni), chromium/copper (Cr/Cu), chromium/silver (Cr/Ag), or chromium/nickel (Cr/Ni), or an alloy or a combination thereof.

15. The manufacturing method according to claim 11, wherein the metal material is at least one of titanium (Ti), nickel (Ni), copper (Cu), chromium (Cr), silver (Ag), gold (Au), tin (Sn), palladium (Pd), nickel/gold (Ni/Au), nickel/palladium/gold (Ni/Pd/Au), nickel/silver (Ni/Ag), or copper/nickel/silver (Cu/Ni/Ag), or an alloy or a combination thereof.

16. The manufacturing method according to claim 11, wherein the metal layer has a thickness of greater than or equal to 90 μm.

17. A highly conductive and heat-dissipating chip, comprising:
a chip body having a first surface and a second surface, wherein the chip body has at least one groove that is formed on the second surface, and at least one portion of the at least one groove has an arc shape;
a seed crystal layer disposed on the second surface and a base wall of the at least one groove; and
a filler body, wherein the filler body is a metal material, and is filled into the at least one groove.

18. The highly conductive and heat-dissipating chip according to claim 17, wherein the seed crystal layer is at least one of titanium (Ti), nickel (Ni), copper (Cu), chromium (Cr), silver (Ag), gold (Au), palladium (Pd), carbon (C), tin (Sn), tungsten (W), titanium/copper (Ti/Cu), titanium/silver (Ti/Ag), titanium/nickel (Ti/Ni), chromium/copper (Cr/Cu), chromium/silver (Cr/Ag), or chromium/nickel (Cr/Ni), or an alloy or a combination thereof.

19. The highly conductive and heat-dissipating chip according to claim 17, wherein the metal material is at least one of titanium (Ti), nickel (Ni), copper (Cu), chromium (Cr), silver (Ag), gold (Au), tin (Sn), palladium (Pd), nickel/gold (Ni/Au), nickel/palladium/gold (Ni/Pd/Au), nickel/silver (Ni/Ag), or copper/nickel/silver (Cu/Ni/Ag), or an alloy or a combination thereof.

20. The highly conductive and heat-dissipating chip according to claim 17, wherein the chip body has a thickness of less than or equal to 100 μm.

21. The highly conductive and heat-dissipating chip according to claim 17, wherein the at least one groove has a depth of greater than or equal to 90 μm.

22. The highly conductive and heat-dissipating chip according to claim 17, wherein the at least one groove has a shape of a vortex.

23. The highly conductive and heat-dissipating chip according to claim 17, wherein one end of the at least one groove is positioned at an edge of the chip body.

24. A highly conductive and heat-dissipating chip, comprising:
a chip body having a first surface and a second surface;
a seed crystal layer disposed on the second surface; and
a metal layer formed by a metal material, wherein the metal layer is disposed on the seed crystal layer;
wherein the chip body has a thickness of less than or equal to 10 μm;
wherein the metal layer has a thickness of greater than or equal to 90 μm.

25. The highly conductive and heat-dissipating chip according to claim 24, wherein the seed crystal layer is at least one of titanium (Ti), nickel (Ni), copper (Cu), chromium (Cr), silver (Ag), gold (Au), palladium (Pd), carbon (C), tin (Sn), tungsten (W), titanium/copper (Ti/Cu), titanium/silver (Ti/Ag), titanium/nickel (Ti/Ni), chromium/copper (Cr/Cu), chromium/silver (Cr/Ag), or chromium/nickel (Cr/Ni), or an alloy or a combination thereof.

26. The highly conductive and heat-dissipating chip according to claim 24, wherein the metal material is at least one of titanium (Ti), nickel (Ni), copper (Cu), chromium (Cr), silver (Ag), gold (Au), tin (Sn), palladium (Pd), nickel/gold (Ni/Au), nickel/palladium/gold (Ni/Pd/Au), nickel/silver (Ni/Ag), or copper/nickel/silver (Cu/Ni/Ag), or an alloy or a combination thereof.
